(19) United States
(12) Patent Application Publication
(10) Pub. No.: US 2026/0087193 A1
(43) Pub. Date: Mar. 26, 2026

(54) PROCESS MODELING USING TUNING FACTORS

(71) Applicant: Honeywell International Inc., Charlotte, NC (US)

(72) Inventors: Shanmuga Sundaram, Bengaluru (IN); Venkata Bharadwaz Vedula, Bengaluru (IN); Vikash Kumar, Bengaluru (IN)

(21) Appl. No.: 18/890,921

(22) Filed: Sep. 20, 2024

(51) Int. Cl. G06F 30/17

(52) U.S. Cl. CPC G06F 30/17

(57) ABSTRACT

Devices, methods, and systems for process modeling using tuning factors are described herein. One method includes receiving, by a computing device, a model representing a physical process, wherein the physical process involves a plurality of equipment items and generates a physically measurable output variable, determining, by the computing device, a predicted value of the physically measurable output variable using the model, and adjusting, in the model, a tuning factor associated with an equipment item of the plurality of equipment items responsive to a difference between the predicted value of the output variable and a physically measured value of the output variable exceeding a difference threshold.

### TECHNICAL FIELD

The present disclosure relates generally to devices, methods, and systems for process modeling using tuning factors.

### BACKGROUND

Mathematical models can be used to represent physical processes. These physical processes include chemical, electrochemical, and/or electromechanical processes, among others. The models can calculate unknown output variables given specified known input variables.

The degree to which a model of a physical process is representative of the actual physical process depends in part on the similarity of the calculated output variables to real field measurements of those output variables. When real field measurements of the output variables of a process deviate from the output variables calculated by a model representing it, the model becomes less representative of the process and therefore less useful.

### BRIEF DESCRIPTION OF THE DRAWINGS

FIG. 1A is a screenshot of an interface depicting a display of an example electrolyzer plant in accordance with one or more embodiments.

FIG. 1B is a schematic diagram of the electrolyzer plant depicted in FIG. 1A.

FIG. 2 is a screenshot of an interface depicting a display of example information associated with selected equipment items of an electrolyzer plant, in accordance with one or more embodiments.

FIG. 3 illustrates an example of a method for a process modeling using tuning factors in accordance with one or more embodiments.

FIG. 4 illustrates a flow chart associated with process modeling using tuning factors in accordance with one or more embodiments.

FIG. 5 is an example of a computing device for process modeling using tuning factors, in accordance with one or more embodiments.

### DETAILED DESCRIPTION

Devices, methods, and systems for process modeling using tuning factors are described herein. One method includes receiving, by a computing device, a model representing a physical process, wherein the physical process involves a plurality of equipment items and generates a physically measurable output variable, determining, by the computing device, a predicted value of the physically measurable output variable using the model, and adjusting, in the model, a tuning factor associated with an equipment item of the plurality of equipment items responsive to a difference between the predicted value of the output variable and a physically measured value of the output variable exceeding a difference threshold.

Physical processes, such as chemical, electrochemical, and/or electromechanical processes, among others, can be represented by mathematical models. Such mathematical models can calculate unknown output variables given specified known input variables. The process of creating, using, and/or modifying a physical process model is referred to herein as process modeling. Process modeling allows the investigation and simulation of a physical process, including the equipment involved in the physical process. Process modeling can facilitate in the improvement of the design and performance of a process.

As previously discussed, however, when real field measurements of the output variables of a process deviate from the output variables calculated by a model representing it, the model becomes less representative of the process and therefore less useful. The present disclosure improves physical process modeling through the use of tuning factors added to equations of the model whose values can be adjusted to reflect (e.g., take into account), in the model, real-world aspects specific to a given process, in order to minimize the difference between the real field measurements of the output variables and the output variables calculated by the model.

As discussed herein, real-world aspects specific to a given process may include, for example, the impacts of the geometry, positioning, or other characteristics of equipment items involved in the process, material characteristics of the process, fluid property characteristics of the process, and/or the effects of phenomena such as heat on the process. Tuning factors generally represent the nudging factors for altering a variable value when the effect of the real-world aspects discussed above are not included, or are only partially included, in the mathematical model. For instance, a model may be created based on a first set of geometrical characteristics, material characteristics, fluid property characteristics, and/heat characteristics associated with the process, whereas a tuning factor corresponds to a second set of geometrical characteristics, material characteristics, fluid property characteristics, and heat characteristics associated with the process.

Additionally, the tuning factors can be adjusted to account for changes over time in a given process, such as those caused by degradation of the process equipment, for instance. Generally speaking, to the extent that a particular process in the real world differs from a modeled process, the tuning factors can be adjusted in the appropriate models of the equation to compensate for these differences.

As an example, a model using mathematical equations representing a physical process can be created based on available models and/or open literature. The formulated mathematical model equations can be reviewed to understand the underlying aspects that each equation represent, including, for instance, equipment characteristics, fluid properties and equipment material properties and degradation over time. Tuning factors can be associated with different equations that represent aspects of equipment items specific to the process being modelled, and initial values (e.g., a value of 1) can be set for the tuning factors. Predicted values of physically measurable output variables generated by the process can be calculated using the model. Actual values of these same output variables can be physically measured in the field. If the difference between these two values exceeds a threshold (e.g., indicating the model is not accurately representative of the actual process), then one or more tuning factors can be adjusted to correct for that difference. The process of adjusting tuning factors can be repeated for multiple data sets and a “best-fit” tuning factor adjustment can be used in the event that different tuning factor adjustments are indicated by the multiple data sets. As a result, a model prediction can be used until a next calibration of tuning factors with reliable predictions.

Constraints can be placed on the tuning factor adjustment. The amount by which a particular tuning factor is allowed to be adjusted may be constrained by the properties and operational limits of the equipment item that is associated with that tuning factor. For example, if the model includes a flow pressure equation, and a tuning factor is used to affect a pressure drop variable in the model, then the range of that tuning factor adjustment can be constrained such that the pressure drop is not allowed to exceed a maximum limit (e.g., an operating limit of the equipment item). These constraints can be set based on knowledge of the environment and/or the particular process itself.

In some cases, the amount by which to adjust the tuning factors can be determined by setting up and solving an optimization problem in which the difference between the predicted value of the output variable and the physically measured value of the output variable is an objective function and is minimized. Such optimization may be particularly useful in more complex processes with multiple data sets and multiple tuning factors available for adjustment. In some cases, the amount by which to adjust the tuning factors can be manually determined and made by a user based on, for instance, their judgement of the results of the process and the direction and amount of deviation of the actual value from the predicted value of the output variable

Embodiments herein improve the representativeness of a model with respect to a physical process (e.g., improve the accuracy with which the model represents the physical process). Accordingly, embodiments herein can facilitate in the improvement of the design and performance of a process. As one example, process modeling in accordance with the present disclosure can improve the design and performance of an electrolyzer plant.

In the following detailed description, reference is made to the accompanying drawings that form a part hereof. The drawings show by way of illustration how one or more embodiments of the disclosure may be practiced.

These embodiments are described in sufficient detail to enable those of ordinary skill in the art to practice one or more embodiments of this disclosure. It is to be understood that other embodiments may be utilized and that mechanical, electrical, and/or process changes may be made without departing from the scope of the present disclosure.

As will be appreciated, elements shown in the various embodiments herein can be added, exchanged, combined, and/or eliminated so as to provide a number of additional embodiments of the present disclosure. The proportion and the relative scale of the elements provided in the figures are intended to illustrate the embodiments of the present disclosure and should not be taken in a limiting sense.

The figures herein follow a numbering convention in which the first digit or digits correspond to the drawing figure number and the remaining digits identify an element or component in the drawing. Similar elements or components between different figures may be identified by the use of similar digits.

As used herein, “a”, “an”, or “a number of” something can refer to one or more such things, while “a plurality of” something can refer to more than one such things. For example, “a number of components” can refer to one or more components, while “a plurality of components” can refer to more than one component.

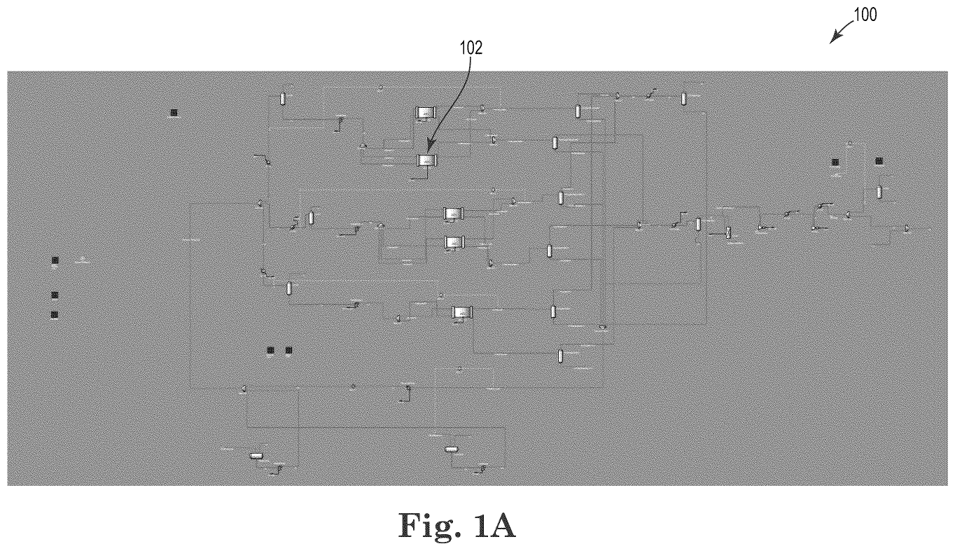

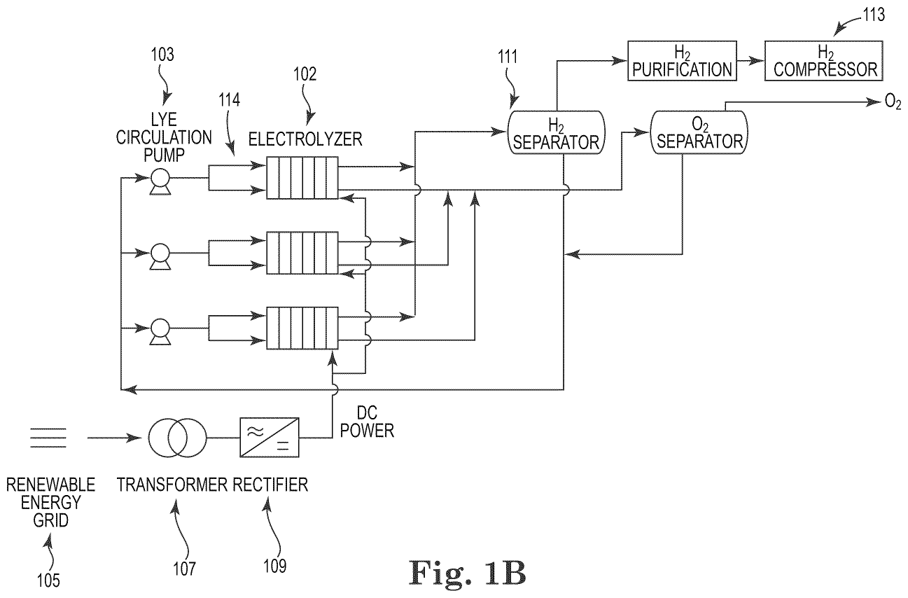

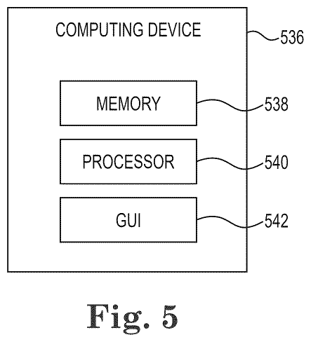

FIG. 1A is a screenshot of an interface, such as, for instance, user interface 542 of computing device 536 further described in connection with FIG. 5, depicting a display of an example electrolyzer plant 100 in accordance with one or more embodiments. FIG. 1B is a schematic diagram of the electrolyzer plant depicted in FIG. 1A. FIG. 1A and FIG. 1B may be cumulatively referred to herein as “FIG. 1.”

The electrolyzer plant (e.g., the equipment of the electrolyzer plant) may be involved with a physical process. For instance, the electrolyzer plant (e.g., the equipment of the electrolyzer plant) may be used to generate hydrogen, for example. While embodiments herein are sometimes described in the context of the specific example of an electrolyzer plant, it is noted that embodiments herein are not so limited. The use of the electrolyzer plant 100 illustrated in FIG. 1 is not intended to be taken in a limiting sense. While an electrolyzer plant may be engaged in a process of generating hydrogen, it will be understood by those of ordinary skill in the art will that other systems employing other equipment items may be involved with different physical processes. Embodiments of the present disclosure are intended to include such processes. For example, embodiments herein are intended to be applicable across various chemical, electrochemical, and/or electromechanical processes, for instance, among other processes.

The plant 100 can operate to generate hydrogen (e.g., using renewable energy like wind and solar power). For instance, the plant 100 can be engaged in the process of generating hydrogen gas. The plant 100 includes a plurality of equipment items involved with the process. A short list of example equipment items includes electrolyzers (e.g., alkaline electrolyzers (AELs)), pumps, valves, conduits, vessels, tanks, transformers, dryers, separators, power supplies, etc. An electrolyzer can include an anode and a cathode separated by an electrolyte. An alkaline electrolyzer may utilize a solution of potassium hydroxide or sodium hydroxide as the electrolyte, for instance.

The plant 100 includes a plurality of electrolyzers arranged in parallel. Each electrolyzer may use between 1 and 5 megawatts of electricity and can produce an amount of hydrogen gas based on its rated power input capacity. As shown in FIG. 1B, the plant 100 includes an electrolyzer 102, fed by a lye circulation pump 103 via an inlet 114. Power generated by a renewable energy grid 105 can be transformed by a transformer 107, rectified by a rectifier 109, and used to power the electrolyzer 102. The hydrogen gas (H₂) generated by the electrolyzer 102 can flow into a separator 111, and then to a compressor 113. It is noted that the equipment illustrated in FIG. 1 is not meant to be taken in a limiting sense, and plant 100 can include other equipment not shown in FIG. 1 involved with generating hydrodgen.

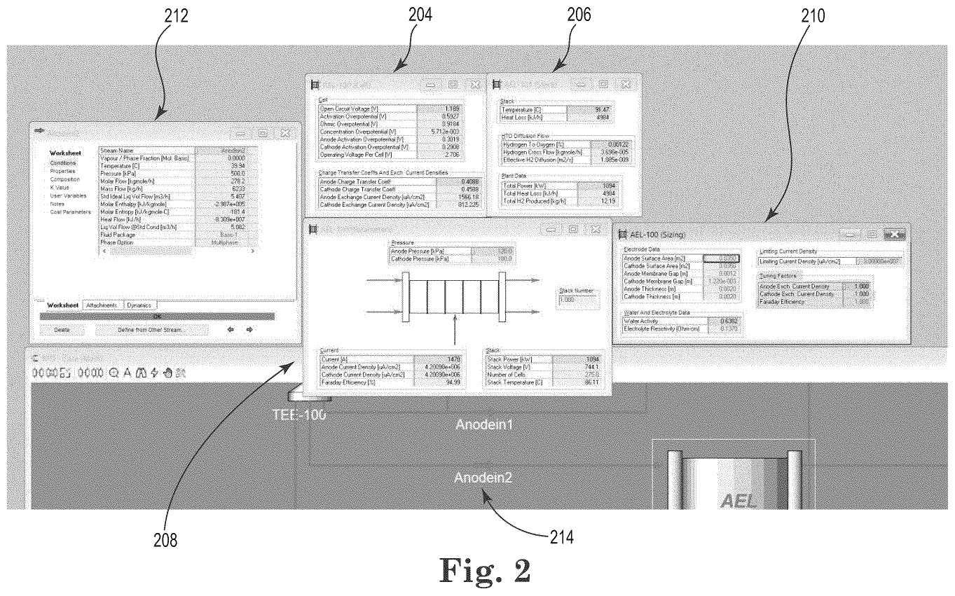

Selection, in the interface (e.g., by a user), of an equipment item can cause information associated with that equipment item to be displayed in the interface. For example, selection of the display element “AEL-100” 102 can cause information associated with the electrolyzer AEL-100 to be displayed. An example illustrating such information is described in more detail in connection with FIG. 2.

FIG. 2 is a screenshot of an interface, such as, for instance, user interface 542 of computing device 536 further described in connection with FIG. 5, depicting a display of example information (e.g., details) associated with selected equipment items of the electrolyzer plant 100 illustrated in FIG. 1, in accordance with one or more embodiments. The information can be displayed in a plurality of information display elements (referred to herein as “windows”) in the interface.

In the example illustrated in FIG. 2, selection of the display element “AEL-100” 102 in FIG. 1 has caused information associated with the electrolyzer AEL-100 to be displayed. A first window 204, with the header “Cell,” is configured to display information associated with the electrolyzer cell of AEL-100. A second window 206, with the header “Stack,” is configured to display more cumulative information associated with a stack of which AEL-100 is a part. A third window 208, with the header “Parameters,” is configured to display parameter information associated with AEL-100. A fourth window 210, with the header “Sizing,” is configured to display size-related information associated with AEL-100. A fifth window 212, with the header “Anodein2,” is configured to display information associated with the inlet to AEL-100. In some embodiments, the fifth window 212 is displayed responsive to a selection of AEL-100. In some embodiments, the fifth window 212 is displayed responsive to a selection of the inlet “Anodein2” 214.

The first window 204 is configured to display information associated with the electrolyzer cell of AEL-100. In some embodiments, this information includes variables associated with the cell. In some embodiments, this information includes variables associated with charge transfer coefficients and exchange current densities. As illustrated in FIG. 2, variables associated with the cell can include open circuit voltage, activation overpotential, ohmic overpotential, concentration overpotential, anode activation overpotential, cathode activation overpotential, and operating voltage per cell. As illustrated in FIG. 2, variables associated with charge transfer coefficients and exchange current densities include anode charger transfer coefficient, cathode charge transfer coefficient, anode exchange current density, and cathode exchange current density.

The second window 206 is configured to display more cumulative information associated with a stack of which AEL-100 is a part. In some embodiments, this information includes variables associated with the stack, including, for instance, a temperature and a heat loss of the stack. In some embodiments, information associated with the stack includes variables associated with hydrogen-to-oxygen (HTO) diffusion flow. As illustrated in FIG. 2, variables associated with HTO diffusion flow can include HTO percentage, hydrogen cross flow, and effective hydrogen diffusion. In some embodiments, information associated with the stack includes variables associated with plant data. As illustrated in FIG. 2, variables associated with plant data can include total power, total heat loss (e.g., rate of heat loss), and total hydrogen produced (e.g., a rate of hydrogen production).

The third window 208 is configured to display parameter information associated with AEL-100. In some embodiments, this information includes pressure-related variables. As illustrated in FIG. 2, pressure-related variables can include anode pressure and cathode pressure. In some embodiments, parameter information includes current-related variables. As illustrated in FIG. 2, current-related variables can include current, anode current density, cathode current density, and Faraday efficiency. In some embodiments, parameter information includes stack-related parameter information. As illustrated in FIG. 2, stack-related parameter information can include stack power, stack voltage, number of cells in the stack, and stack temperature.

The fourth window 210 is configured to display size-related information associated with AEL-100. In some embodiments, size-related information includes electrode data. As illustrated in FIG. 2, electrode data can include anode surface area, cathode surface area, anode membrane gap, cathode membrane gap, anode thickness, and cathode thickness. In some embodiments, size-related information includes water and electrolyte data. As illustrated in FIG. 2, water and electrolyte data can include water activity and electrolyte resistivity. In some embodiments, size-related information includes a limiting current density.

In some embodiments, the fourth window 210 includes a number of adjustable tuning factors associated with AEL-100. As shown in the example illustrated in FIG. 2, the fourth window 210 includes three tuning factors: anode exchange current density, cathode exchange current density, and Faraday efficiency. It is noted that while three tuning factors are displayed in the fourth window 210 in the example illustrated in FIG. 2, embodiments of the present disclosure are not so limited. For instance, any number of tuning factors associated with a selected equipment item can be included in any respective window displayed in response to the selection. The manner in which tuning factors are displayed in FIG. 2 is not intended to be taken in a limiting sense. Tuning factors, their use, and their adjustment, is described in further detail below.

The fifth window 212 is configured to display information associated with the inlet to AEL-100 (e.g., Anodein2). The inlet Anodein2 214 can be a conduit inlet to AEL-100 and is, in some embodiments, considered an equipment item as described herein, though it may be characterized more by the fluid that flows through it. Stated differently, where embodiments herein refer to an inlet, such reference can be understood to refer to an inlet or an input to a process.

In some embodiments, the fifth window 212 includes a plurality of tabs. As illustrated in FIG. 2, the fifth window 212 can include a worksheet tab, an attachments tab, and a dynamics tab. Within the worksheet tab, as illustrated in FIG. 2, several subcategories can be selected. These subcategories include conditions, properties, composition, k value, user variables, notes, and cost parameters. In the example shown, the conditions subcategory is selected, and several conditions are listed within the fifth window 212. The conditions include stream name, vapor/phase fraction, temperature, pressure, molar flow, mass flow, standard ideal liquid volume flow, molar enthalpy, molar entropy, heat flow, liquid volume flow, fluid package, and phase option.

The physical process (e.g., hydrogen generation) carried out by the plant 100, previously described in connection with FIG. 1, can be represented by mathematical models. For example,, the physical processes performed by individual equipment items can be represented by mathematical models. Models can use a number of mathematical equations to calculate output variables of the process given specified known input variables. In the example of electrolyzer (AEL-100) 102, input variables can include, for example, input power, voltage, inlet flow rate, and inlet temperature. Output variables can include an amount of hydrogen produced, operating temperature, and a voltage required to produce a given amount of hydrogen, for instance.

As previously discussed, however, real (e.g., actual) field measurements of the output variables of a process can deviate from the output variables calculated by a model representing it. Embodiments herein can allow for the adjustment of the tuning factors (e.g., the tuning factors shown in the window 210), in order to reduce (e.g., minimize) the difference between the real field measurements of the output variables and the output variables calculated by the model, such that the model provides a more accurate representation of the process.

It is noted that in some cases, actual measured output variables may not be available for each individual equipment item. Rather, the actual measured output variables may be cumulative to the plurality of equipment items. Referring back to the plant 100, the plurality of parallel electrolyzers may share a common hydrogen outlet. In such cases, a tuning factor adjustment may be carried out for several (or all) of a type of equipment item of the process (e.g., electrolyzers of the plant 100) simultaneously.

In some embodiments, a model representing a physical process can be received from available literature. In some embodiments, a model corresponding to an equipment item involved with the process, for instance, is received from a manufacturer or a vendor of the equipment item. As previously discussed, however, real-world aspects specific to a given process may render the model sufficiently unrepresentative of the process such that its usefulness is diminished. Geometry of the plant 100, positioning of the various equipment items, or other characteristics of equipment items involved in the process, material characteristics of the process, fluid property characteristics of the process, and the effects of phenomena such as heat on the process, among other things can all have effects on the accuracy of the model.

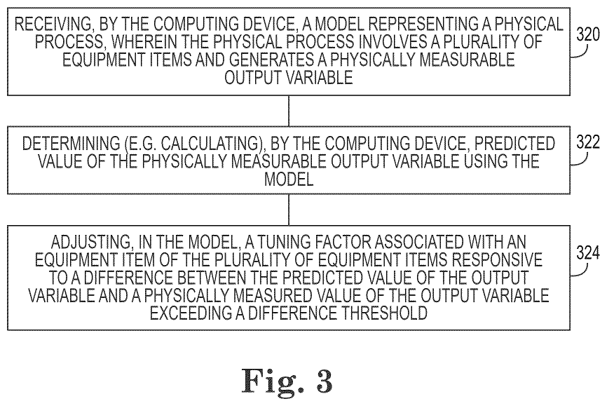

FIG. 3 illustrates an example of a method for a process modeling using tuning factors in accordance with one or more embodiments. The method can be performed by, for example, a computing device such as that described below connection with FIG. 5, for instance.

At 320, the method includes receiving, by the computing device, a model representing a physical process, wherein the physical process involves a plurality of equipment items and generates a physically measurable output variable. As an example, with reference to the example plant previously described in connection with FIG. 1 and FIG. 2, the model can represent the physical process of hydrogen generation using a plurality of electrolyzer equipment items. With respect to the example, in some embodiments, the physically measurable output variable is an amount of hydrogen produced; in some embodiments, the physically measurable output variable is operating temperature, in some embodiments, the physically measurable output variable is a voltage required to produce a given amount of hydrogen.

In some examples, the model can be created based on additional models. For instance, the model can be created based on available models and/or open literature input to the computing device.

At 322, the method includes determining (e.g., calculating), by the computing device, a predicted value of the physically measurable output variable using the model. The predicted value can be determined via a number of equations of the model based on a plurality of input variables. In the example of the plant previously described in connection with FIGS. 1 and 2, the input variables can include input power, voltage, inlet flow rate, and/or inlet temperature. For example, the computing device can determine, using the input variables and the model, a predicted value of total hydrogen production of 13.19 kilograms per hour.

At 324, the method includes adjusting, in the model, a tuning factor associated with an equipment item of the plurality of equipment items responsive to a difference between the predicted value of the output variable and a physically measured value of the output variable exceeding a difference threshold. Determining that the difference between the predicted value of the output variable and the physically measured value of the output variable exceeds a difference threshold includes measuring the value of the output variable, and/or receiving the measured value. In an example, the measured value of total hydrogen production is 12.19 kilograms per hour, 1 kilogram per hour less than the model-predicted value, discussed above.

It is to be understood that differences between predicted values and physically measured values may commonly occur. However, a difference that is low enough (e.g., below the threshold) may be acceptable, while a difference that is high enough (e.g., exceeds the threshold) may not be acceptable. For example, a difference of 0.001 kilograms per hour for total hydrogen production may be acceptable while a difference of 1 kilogram per hour may be unacceptable. At such a difference, the predictive capacity of the model can be said to have deviated far enough from the actual measured value that the model may no longer be useful for its purpose. Configuration of the difference threshold is, in some embodiments, a matter of knowledge and/or experience with the process. For instance, the amount by which a model-predicted value is allowed to deviate from a physically measured value can be determined based on knowledge and/or experience with the process and/or the equipment item(s) involved. Those of skill in the art will appreciate that the relative size of the difference threshold will depend on the type of the variable being predicted/measured and the nature of the process itself. In some embodiments, for instance, the difference threshold is 0. Where a model-predicted value is said to “match” a measured value herein, it is to be understood that the difference between the two is within the difference threshold. Where a model-predicted value is said to not match a measured value herein, it is to be understood that the difference between the two exceeds the difference threshold.

Assuming, in the example, that 1 kilogram per hour exceeds the difference threshold, a tuning factor can be adjusted to narrow the gap between predicted and measured values. As previously discussed, before any adjustments are made, an initial value of the tuning factor can be set, and the predicted value of the output variable can be determined with the tuning factor set at the initial value. Returning to the example above, when the predicted value was previously determined, the tuning factor was set at its initial value. In some embodiments, that initial value is 1, though other values may be used and are in accordance with the present disclosure.

In some embodiments, the determination of the amount by which to adjust the tuning factor is carried out manually. For example, a user (e.g., a plant technician or supervisor) can utilize the interfaces described above in connection with FIG. 2 to adjust the tuning factor by, for instance, entering new values (e.g., numerical values) for one or more of the tuning factors. As these values are adjusted, some embodiments include re-determining, in real time, an updated predicted value. For example, after the tuning factor has been adjusted, the computing device can determine a subsequent predicted value of the output variable using the model with the adjusted tuning factor. The tuning factor can then be adjusted further responsive to the difference between the subsequently predicted value and the physically measured value of the output variable still exceeding the difference threshold. This process can continue until the difference threshold is not exceeded. The user can thus adjust the tuning factor by an amount that brings the displayed predicted value as close as possible to the physically measured value.

Constraints can be placed on the tuning factor adjustment. For instance, the amount by which a tuning factor is capable of being adjusted can be constrained. In some embodiments, the amount by which a tuning factor is capable of being adjusted is constrained based on an operational limit associated with the equipment item. For example, if the model includes a flow pressure equation, and a tuning factor is used to affect a pressure drop variable in the model, then the range of that tuning factor adjustment can be constrained such that the pressure drop is not allowed to exceed a maximum limit (e.g., an operating limit of the equipment item). These constraints can be set based on knowledge of the environment and/or the particular process itself.

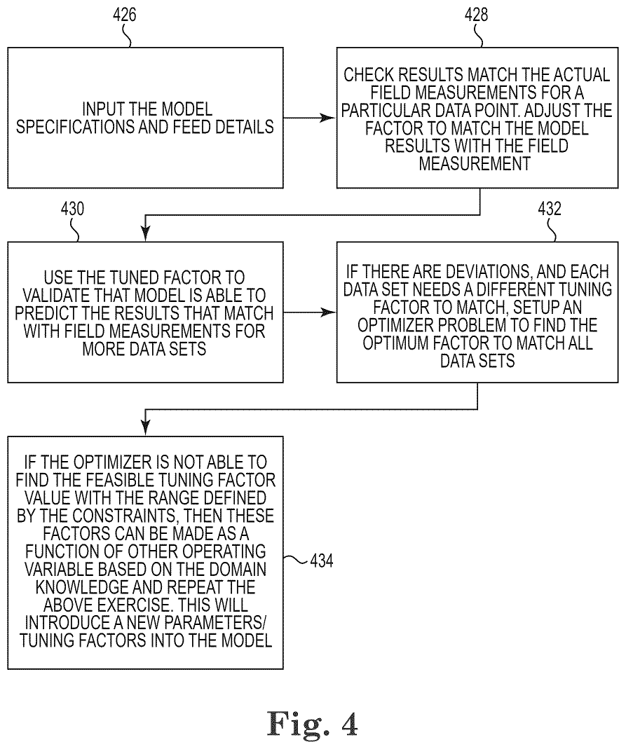

In some embodiments, the determination of the amount by which to adjust the tuning factor is carried out automatically (e.g., without manual user adjustment). For example, as discussed further below in connection with FIG. 4, determining an amount by which to adjust a tuning factor can include solving an optimization problem in which the difference between the predicted value of the output variable and the physically measured value of the output variable is an objective function.

Blocks 322 and 324 can be performed in an analogous manner for additional (e.g., different) output variables generated by the process and additional (e.g., different) equipment items of the plurality of equipment items. For example, the computing device can determine a predicted value of a different physically measurable output variable generated by the process using the model. The computing device can then adjust, in the model, a different tuning factor associated with a different equipment item of the plurality of equipment items responsive to the difference between the predicted value of the different output variable and a physically measured value of the different output variable exceeding a different difference threshold, in a manner analogous to that previously described herein. As an additional example, another (e.g., a different) tuning factor associated with the first equipment item can be adjusted responsive to the difference between the predicted and measured values of the first output variable exceeding the difference threshold, in a manner analogous to that previously described herein.

FIG. 4 illustrates a flow chart associated with process modeling using tuning factors in accordance with one or more embodiments. The steps of the flow chart illustrated in FIG. 4 can be performed by, for example, a computing device such as that described below connection with FIG. 5, for instance.

At 426, the model specifications and feed details are input. Feed details may refer to input variables. Referring back to the example of the electrolyzer plant, feed details can include the feed fluid Anodein2 to the electrolyzer AEL-100.

At 426, the model specifications and feed details are input. Feed details may refer to input variables. Referring back to the example of the electrolyzer plant, feed details can include the feed fluid Anodein2 to the electrolyzer AEL-100. The model specifications can be received from, for example, available models and/or open literature.

At 428, a check is performed to determine whether the result of the model prediction (e.g., the value of a physically measurable output variable predicted using the model) matches the actual field measurement of the output variable and, if they do not, a tuning factor is adjusted (e.g., manually adjusted) to match the model result with the field measurement. This adjustment can be carried out in accordance with the method previously described in connection with FIG. 3, for instance.

At 430, the adjusted tuning factor is used to validate that the model is able to predict results that match field measurements for additional data sets. Additional data sets can refer to data sets gathered over a period of operation of the process. Additional data sets can refer to data sets gathered over different operational conditions. For example, referring back to the example of the electrolyzer plant, the electrolyzer plant can be operated over a first period of time using an adjusted Faraday efficiency tuning factor of 0.94 such that the predicted value of hydrogen production matches the measured value of hydrogen production. Over a second period of time, however, different operating conditions may render the tuning factor of 0.94 inappropriate. Different operating conditions can include, for example, different power levels, different quantities of electrolyzers in use, different ambient temperatures, etc.

At 432, if there are deviations between the predicted results and actual field measurements, and each data set calls for a different tuning factor to match, an optimizer problem can be set up to find the optimum tuning factor to match the data sets. If, for example, a first data set calls for a tuning factor of 0.94, a second data set calls for a tuning factor of 0.089, a third data set calls for a tuning factor of 0.084, and a fourth data set calls for a tuning factor of 0.97, an optimizer problem can be set up to find the optimum tuning factor to match the four data sets. Values of the plurality of tuning factors can be designated as optimization variables of the optimization problem. The difference between the predicted value of the output variable and the physically measured value of the output variable can be designated as an objective function of the optimization problem. It should be appreciated that as the quantity of data sets increases, the use of manual tuning factor adjustment becomes unwieldy and is more likely to be overtaken by the use of optimization. Similarly, as the quantity of different tuning factors increases, the use of manual tuning factor adjustment is more likely to be overtaken by the use of optimization.

At 434, if the optimizer is not able to find a feasible tuning factor value within tuning factor constraints, then the tuning factors themselves can be made a function of other operating variables based on knowledge of the process and/or the domain and step 432 can be repeated. For instance, it may be that the currently available tuning factors, even adjusted to the limits of their constraints, are not sufficient to match the predicted value of the output variable with the physically measured value of the output variable. New parameters and/or new tuning factors may thus be introduced to the model.

As previously discussed, embodiments herein can be used to determine degradation (e.g., degradation patterns) of equipment involved in a process. Returning to the example of the electrolyzer plant described above in connection with FIG. 1 and FIG. 2, assume the electrolyzer has power input of 1 megawatt and an Anode and Cathode alkali solution flowing at a certain flowrate, temperature and pressure. All these variables are measured in the plant and controlled during the plant operation. Similarly, outlet values including outlet temperature, pressure, H₂ generated, and voltage and current across the electrolyzer are all measured. In the model, when the measured inputs are specified, the model can be expected to predict the outlet measured values. At a first pass, the parameter values of the model are adjusted to match the plant measured outlet values for given set of inlet values. The tuning factors described above (anode exchange current density, cathode exchange current density, and Faraday efficiency) represent characteristics of components constituting the electrolyzer AEL-100. Once the initial tuning of parameters is completed with results of the model matching with measured outlet conditions, then the model can be used to study degradation patterns of the equipment. Until this time the tuning factors are all kept at their default value of 1.

The tuning factors are adjusting factors introduced in certain selected equations of the model and may be used as adjustments to represent the degradation of any equipment component or activity of the component in the process. For example, when the plant is operating for 6 months, for the same amount of power input and other inlet conditions, the previous hydrogen flowrate may not be obtainable. To simulate this condition, Faraday efficiency tuning factor or one or both of the exchange current density tuning factors can be adjusted to get the hydrogen production, which will be lesser, in a degraded electrolyzer condition.

In some embodiments, one (e.g., a single) parameter is adjusted. In some embodiments, a set of parameters is adjusted. This process can be repeated for long horizon data sets. For example, with 2 years of operating data, this process can be carried out for each data point and a set of different tuning factor values can be obtained for each data point. A trend of the tuning factors can be determined, and a degradation pattern of the components can be inferred. In addition, the tuning factor rate of change and pattern can be imposed on the input operating variables to help technicians and/or operators understand what operating procedures should be modified to extend the life of the plant.

FIG. 5 is an example of a computing device 536 for process modeling using tuning factors, in accordance with one or more embodiments. As illustrated in FIG. 5, the computing device 536 can include a memory 538, a processor 540, and user interface 542 for process modeling using tuning factors, in accordance with the present disclosure.

The memory 538 can be any type of storage medium that can be accessed by the processor 540 to perform various examples of the present disclosure. For example, the memory 538 can be a non-transitory computer readable medium having computer readable instructions (e.g., executable instructions/computer program instructions) stored thereon that are executable by the processor 540 for process modeling using tuning factors in accordance with the present disclosure.

The memory 538 can be volatile or nonvolatile memory. The memory 538 can also be removable (e.g., portable) memory, or non-removable (e.g., internal) memory. For example, the memory 538 can be random access memory (RAM) (e.g., dynamic random access memory (DRAM) and/or phase change random access memory (PCRAM)), read-only memory (ROM) (e.g., electrically erasable programmable read-only memory (EEPROM) and/or compact-disc read-only memory (CD-ROM)), flash memory, a laser disc, a digital versatile disc (DVD) or other optical storage, and/or a magnetic medium such as magnetic cassettes, tapes, or disks, among other types of memory.

Further, although memory 538 is illustrated as being located within computing device 536, embodiments of the present disclosure are not so limited. For example, memory 538 can also be located internal to another computing resource (e.g., enabling computer readable instructions to be downloaded over the Internet or another wired or wireless connection).

The processor 540 may be a central processing unit (CPU), a semiconductor-based microprocessor, and/or other hardware devices suitable for retrieval and execution of machine-readable instructions stored in the memory 538.

In some embodiments, the instructions include instructions to receive a model representing a physical process, wherein the physical process involves a plurality of equipment items and generates a physically measurable output variable, as previously described herein. In some embodiments, the instructions include instructions to determine a predicted value of the physically measurable output variable using the model, as previously described herein. In some embodiments, the instructions include instructions to determine that a difference between the predicted value of the output variable and a physically measured value of the output variable exceeds a difference threshold, as previously described herein. In some embodiments, the instructions include instructions to determine a respective amount to adjust each of a plurality of tuning factors associated with an equipment item of the plurality of equipment items, as previously described herein. In some embodiments, the instructions include instructions to adjust each of the plurality of tuning factors by the respective amounts, as previously described herein.

In some embodiments, the instructions include instructions to perform a plurality of adjustments to the tuning factor over a time period and determine a rate of change of the tuning factor based on the plurality of adjustments. In some embodiments, the instructions include instructions to determine a degradation pattern of the equipment item based on the rate of change. In some embodiments, the instructions include instructions to modify an operating procedure associated with the equipment item based on the rate of change. In an example, modifying an operating procedure includes beginning to operate an equipment item at a constant power level rather than a varying power level, as previously done.

As shown in FIG. 5, computing device 536 can include a user interface 542. A user of computing device 536 can interact with computing device 536 via user interface 542. For example, the user interface 542 can provide (e.g., display and/or present) information to the user of computing device 536, and/or receive information from (e.g., input by) the user of computing device 536. For instance, in some embodiments, user interface 542 can include a graphical user interface (GUI) that can provide and/or receive information to and/or from the user of computing device 536. The GUI can be, for instance, a touch-screen (e.g., the GUI can include touch-screen capabilities). As an additional example, user interface 542 (e.g., the GUI) can include a keyboard and/or mouse. However, embodiments of the present disclosure are not limited to a particular type of user interface.

As an example, user interface 542 can provide (e.g., display) the screenshots previously described in connection with FIGS. 1 and 2 to a user of computing device 567. Further, user interface 542 can receive selections of displayed equipment items, and adjustments of tuning factors associated with the equipment items, as previously described herein.

The user interfaces 336, 346, and 356 can each be localized to any language. For example, the user interfaces 336, 346, and 356 can each display information in any language, such as English, Spanish, German, French, Mandarin, Arabic, Japanese, Hindi, etc.

Although specific embodiments have been illustrated and described herein, those of ordinary skill in the art will appreciate that any arrangement calculated to achieve the same techniques can be substituted for the specific embodiments shown. This disclosure is intended to cover any and all adaptations or variations of various embodiments of the disclosure.

It is to be understood that the above description has been made in an illustrative fashion, and not a restrictive one. Combination of the above embodiments, and other embodiments not specifically described herein will be apparent to those of skill in the art upon reviewing the above description.

The scope of the various embodiments of the disclosure includes any other applications in which the above structures and methods are used. Therefore, the scope of various embodiments of the disclosure should be determined with reference to the appended claims, along with the full range of equivalents to which such claims are entitled.

In the foregoing Detailed Description, various features are grouped together in example embodiments illustrated in the figures for the purpose of streamlining the disclosure. This method of disclosure is not to be interpreted as reflecting an intention that the embodiments of the disclosure require more features than are expressly recited in each claim.

Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. A method, comprising:
receiving, by a computing device, a model representing a physical process, wherein the physical process involves a plurality of equipment items and generates a physically measurable output variable;
determining, by the computing device, a predicted value of the physically measurable output variable using the model; and
adjusting, in the model, a tuning factor associated with an equipment item of the plurality of equipment items responsive to a difference between the predicted value of the output variable and a physically measured value of the output variable exceeding a difference threshold.

2. The method of claim 1, wherein the method includes:
determining, by the computing device, a subsequent predicted value of the output variable using the model with the adjusted tuning factor; and
adjusting, in the model, the adjusted tuning factor responsive to a difference between the subsequent predicted value of the output variable and the physically measured value of the output variable exceeding the difference threshold.

3. The method of claim 1, wherein the method includes:
determining, by the computing device, a predicted value of a different physically measurable output variable generated by the process using the model; and
adjusting, in the model, a different tuning factor associated with a different equipment item of the plurality of equipment items responsive to a difference between the predicted value of the different output variable and a physically measured value of the different output variable exceeding a different difference threshold.

4. The method of claim 1, wherein an amount by which the tuning factor is adjusted is constrained based on an operational limit associated with the equipment item.

5. The method of claim 1, wherein the method includes determining, by the computing device, an amount by which to adjust the tuning factor by solving an optimization problem in which the difference between the predicted value of the output variable and the physically measured value of the output variable is an objective function.

6. The method of claim 1, wherein the method includes receiving, by the computing device, an amount by which to adjust the tuning factor.

7. The method of claim 1, wherein the method includes:
setting an initial value of the tuning factor; and
determining, by the computing device, the predicted value of the output variable using the model with the tuning factor set at the initial value.

8. The method of claim 7, wherein the initial value is 1.

9. The method of claim 1, wherein the method includes creating, by the computing device, the model representing the physical process based on additional models.

10. A non-transitory machine-readable medium having instructions stored thereon which, when executed by a processor, cause the processor to:
receive a model representing a physical process, wherein the physical process involves a plurality of equipment items and generates a physically measurable output variable;
determine a predicted value of the physically measurable output variable using the model; and
determine that a difference between the predicted value of the output variable and a physically measured value of the output variable exceeds a difference threshold;
determine a respective amount by which to adjust each of a plurality of tuning factors associated with an equipment item of the plurality of equipment items; and
adjust each of the plurality of tuning factors by the respective amounts.

11. The medium of claim 10, wherein the instructions to determine the respective amount to adjust each of the plurality of tuning factors associated with the equipment item of the plurality of equipment items include instructions to solve an optimization problem.

12. The medium of claim 11, including instructions to designate values of the plurality of tuning factors as optimization variables of the optimization problem.

13. The medium of claim 11, including instructions to designate the difference between the predicted value of the output variable and the physically measured value of the output variable as an objective function of the optimization problem.

14. A system for process modeling using tuning factors, comprising:
a plurality of equipment items involved with a physical process that generates a physically measurable output variable; and
a computing device, configured to:
receive a model representing the physical process;
determine a predicted value of the physically measurable output variable using the model;
receive the physically measured value of the output variable; and
adjust, in the model, a tuning factor associated with an equipment item of the plurality of equipment items responsive to a difference between the predicted value of the output variable and the physically measured value of the output variable exceeding a difference threshold.

15. The system of claim 14, wherein the instructions include instructions to:
adjust, in the model, another tuning factor associated with the equipment item of the plurality of equipment items responsive to the difference between the predicted value of the output variable and the measured value of the output variable exceeding the difference threshold.

16. The system of claim 14, wherein the instructions include instructions to:
perform a plurality of adjustments to the tuning factor over a time period; and
determine a rate of change of the tuning factor based on the plurality of adjustments.

17. The system of claim 16, wherein the instructions include instructions to determine a degradation pattern of the equipment item based on the rate of change.

18. The system of claim 16, wherein the instructions include instructions to modify an operating procedure associated with the equipment item based on the rate of change.

19. The system of claim 14, wherein the model is created based on a first set of geometrical characteristics, material characteristics, fluid property characteristics, and heat characteristics, and wherein the tuning factor corresponds to a second set of geometrical characteristics, material characteristics, fluid property characteristics, and heat characteristics.

20. The system of claim 14, wherein the plurality of equipment items includes an electrolyzer.
